(19) United States
(12) Patent Application Publication
(10) Pub. No.: US 2025/0093653 A1
(43) Pub. Date: Mar. 20, 2025

(54) HEAD-MOUNTED DISPLAY DEVICES, GLASSES-TYPE DISPLAY DEVICES, AND DISPLAY DEVICES HAVING THESE FORMS

(71) Applicant: SAMSUNG DISPLAY CO., LTD., YONGIN-SI (KR)

(72) Inventors: SU JEONG KIM, Yongin-si (KR); GUN SHIK KIM, Yongin-si (KR); JOON HYUNG PARK, Yongin-si (KR); JI NA SEO, Yongin-si (KR); SEUNG HWAN CHO, Yongin-si (KR)

(21) Appl. No.: 18/668,789

(22) Filed: May 20, 2024

(30) Foreign Application Priority Data
Sep. 19, 2023 (KR) 10-2023-0124548

(51) Int. Cl. G02B 27/01

(52) U.S. Cl. CPC G02B 27/0172; G02B 27/0101; G02B 27/0149; G02B 27/0176; G02B 2027/011; G02B 2027/0123; G02B 2027/0132; G02B 2027/0163; G02B 2027/0178

(57) ABSTRACT

A mobile display device includes a first display device that provides images to a user's left eye, a second display device that provides images to the user's right eye, a display device housing that accommodates the first display device and the second display device, and a housing cover that covers the display device housing and includes a first eyepiece aligned with the first display device and a second eyepiece aligned with the second display device. Each of the first display device and the second display device includes a display panel and a circuit board disposed at one end of the display panel and that includes a driver circuit. The circuit board of the first display device and the circuit board of the second display device are symmetrically arranged with respect to a center of the housing cover located between the first eyepiece and the second eyepiece.

This application claims priority under 35 U.S.C. § 119 from Korean Patent Application No. 10-2023-0124548, filed on Sep. 19, 2023 in the Korean Intellectual Property Office, the contents of which are herein incorporated by reference in their entirety.

### TECHNICAL FIELD

The present disclosure relates to a head-mounted display device, a glasses-type display device, and displays that have these forms.

### DISCUSSION OF THE RELATED ART

A wearable device is being developed that is in the form of glasses or a helmet and forms a focus at a location close to the user's eyes. For example, a wearable device may be a head mounted display (HMD) device or an augmented reality (AR) glass. Such a wearable device provides a user with an AR screen or a virtual reality (VR) screen.

A wearable device such as a HMD device or AR glasses have display specifications of at least 2,000 PPI (pixels per inch) to allow users to use it for a long time without becoming dizzy. To this end, an organic light-emitting diode on silicon (OLEDoS) technology is emerging, which is a high-resolution small organic light-emitting element display device. The OLEDoS is a technology for disposing organic light-emitting diodes (OLEDs) on a semiconductor wafer substrate on which a complementary metal oxide semiconductor (CMOS) is disposed.

A display panel of a display device that uses the OLEDoS technology includes an optical layer that includes a lens array on an emission material layer. The lens array includes a structure that increases the ratio of light directed to the front side of the display device. The location of an optical sweet spot of a lens array determines the field of view (FoV). Since distortion of images shown to a user can occur depending on the location of the optical sweet spot of the lens array, the lens array should be optimized.

### SUMMARY

Embodiments of the present disclosure provide a head-mounted display device, a glasses-type display device and display devices that have these forms that can expand the field of view and reduce image distortion by correcting the location of an optical sweet spot of a lens array.

Embodiments of the present disclosure provide a head-mounted display device, a glasses-type display device and display devices that have these forms that can expand the field of view and reduce image distortion by correcting the location of an optical sweet spot, and can save the fabrication cost with a simple structure.

According to an embodiment of the present disclosure, a mobile display device includes a first display device that provides images to a user's left eye, a second display device that provides images to the user's right eye, a display device housing that accommodates the first display device and the second display device, and a housing cover that covers a face of the display device housing and includes a first eyepiece aligned with the first display device and a second eyepiece aligned with the second display device. Each of the first display device and the second display device includes a display panel that includes an emission material layer, an optical layer that includes lenses disposed on the emission material layer, and a circuit board disposed at one end of the display panel and that includes a driver circuit that drives the display panel. The circuit board of the first display device and the circuit board of the second display device are symmetrically arranged with respect to a center of the housing cover located between the first eyepiece and the second eyepiece.

A first circuit board of the first display device may be disposed in a first space of the display device housing located in a first direction from the first eyepiece, and a second circuit board of the second display device may be disposed in a second space of the display device housing located in a second direction opposite to the first direction from the second eyepiece.

The first display device may include a first display panel that includes a first emission material layer and a first optical layer, and a first circuit board disposed in the first direction from the first display panel. The second display device may include a second display panel that includes a second emission material layer and a second optical layer, and a second circuit board disposed in the second direction from the second display panel.

First lenses of the first optical layer and second lenses of the second optical layer may be symmetrically arranged with respect to the center of the housing cover.

A first optical sweet spot of the first optical layer may be shifted from a center of the first display panel in a third direction, and a second optical sweet spot of the second optical layer may be shifted from a center of the second display panel in a fourth direction opposite to the third direction.

The first lenses may include a first central lens associated with the first optical sweet spot and that is aligned with a center of a sub-pixel of the first emission material layer, and first peripheral lenses disposed outside the first central lens and that are shifted by a predetermined distance from the center of the sub-pixel of the first emission material layer.

The predetermined distance of the first peripheral lenses may increase away from the first optical sweet spot.

The first peripheral lenses may include first radius lenses located at a first radius distance from the first optical sweet spot and that are shifted and aligned by a first distance from the center of the sub-pixel, and second radius lenses located at a second radius distance greater than the first radius distance from the first optical sweet spot and that are shifted and aligned by a second distance from the center of the sub-pixel.

The first direction is a direction from the first display panel to the center of the housing cover, the second direction is a direction from the second display panel to the center of the housing cover, the third direction is opposite to the first direction, and the fourth direction is opposite to the second direction.

The first direction and the third direction are directions from the center of the housing cover toward the first display panel, and the second direction and the fourth direction are directions from the center of the housing cover toward the second display panel.

The first direction is an upward direction of the housing cover, the second direction is a downward direction of the housing cover, the third direction is directed from the center of the housing cover toward the first display panel, and the fourth direction is directed from the center of the housing cover toward the second display panel.

The mobile display device may be a head-mounted display device or a glasses-type display device that provides virtual reality or augmented reality.

According to an embodiment of the present disclosure, a head-mounted display device includes a first display device that provides images to a user's left eye, a second display device that provides images to the user's right eye, a display device housing that accommodates the first display device and the second display device, and a housing cover that covers a face of the display device housing and includes a first eyepiece aligned with the first display device and a second eyepiece aligned with the second display device. Each of the first display device and the second display device includes a display panel that includes an emission material layer, an optical layer that includes lenses disposed on the emission material layer, and a circuit board disposed at one end of the display panel and that includes a driver circuit that drives the display panel. The circuit board of the first display device and the circuit board of the second display device are symmetrically arranged with respect to a center of the housing cover located between the first eyepiece and the second eyepiece.

A first circuit board of the first display device may be disposed in a first space of the display device housing located in a first direction from the first eyepiece, and a second circuit board of the second display device may be disposed in the second space of the display device housing located in a second direction opposite to the first direction from the second eyepiece.

The first display device may include a first display panel that includes a first emission material layer and a first optical layer, and a first circuit board disposed in the first direction from the first display panel. The second display device may include a second display panel that includes a second emission material layer and a second optical layer, and a second circuit board disposed in the second direction from the second display panel.

First lenses of the first optical layer and second lenses of the second optical layer may be symmetrically arranged with respect to the center of the housing cover.

According to an embodiment of the present disclosure, a glasses-type display device includes a first display device that provides images to a user's left eye, a second display device that provides images to the user's right eye, a display device housing that accommodates the first display device and the second display device, and a housing cover that covers a face of the display device housing and includes a first eyepiece aligned with the first display device and a second eyepiece aligned with the second display device. Each of the first display device and the second display device may include a display panel that includes an emission material layer, an optical layer that includes lenses disposed on the emission material layer, and a circuit board disposed at one end of the display panel and that includes a driver circuit that drives the display panel. The circuit board of the first display device and the circuit board of the second display device may be symmetrically arranged with respect to a center of the housing cover located between the first eyepiece and the second eyepiece.

A first circuit board of the first display device may be disposed in a first space of the display device housing located in a first direction from the first eyepiece, and a second circuit board of the second display device may be disposed in the second space of the display device housing located in a second direction opposite to the first direction from the second eyepiece.

The first display device may include a first display panel that includes a first emission material layer and a first optical layer, and a first circuit board disposed in the first direction from the first display panel. The second display device may include a second display panel that includes a second emission material layer and a second optical layer, and a second circuit board disposed in the second direction from the second display panel.

First lenses of the first optical layer and second lenses of the second optical layer may be symmetrically arranged with respect to the center of the housing cover.

According to a head-mounted display device, a glasses-type display device, and display devices that have these forms according to embodiments, the field of view can be expanded and image distortion can be reduced by correcting the location of the optical sweet spot of the lens array.

In addition, according to embodiments, a head-mounted display device, a glasses-type display device and display devices that have these forms have a simple structure and reduced fabrication costs.

### BRIEF DESCRIPTION OF THE DRAWINGS

FIG. 1 is a perspective view of a head-mounted display device according to an embodiment of the present disclosure.

FIG. 2 is an exploded perspective view of a head-mounted display device of FIG. 1.

FIG. 3 is a perspective view of a head-mounted display device according to an embodiment of the present disclosure.

FIG. 4 is an exploded, perspective view of a display device according to an embodiment of the present disclosure.

FIG. 5 is a cross-sectional view of a part of a display panel according to an embodiment of the present disclosure.

FIG. 6 illustrates distortion that depends on the location of an optical sweet spot of a lens.

FIG. 7 shows a display device according to Comparative Example in which a decenter structure that corrects the location of an optical sweet spot is not used.

FIG. 8 shows a display device according to an embodiment in which a decenter structure that corrects the location of an optical sweet spot is used.

FIG. 9 is a cross-sectional view of an alignment of a central lens located at an optical sweet spot and sub-pixels.

FIG. 10 is a cross-sectional view of an alignment of a first radius lens located at a first radius distance from an optical sweet spot and sub-pixels.

FIG. 11 is a cross-sectional view of an alignment of a second radius lens located at a second radius distance from an optical sweet spot and sub-pixels.

FIG. 12 compares a user's field of views (FoV) with and without a decenter structure that corrects the location of the optical sweet spot.

FIGS. 13 to 15 show a variety of embodiments in which a circuit board of a first display device and a circuit board of a second display device are symmetrically arranged.

### DETAILED DESCRIPTION

Embodiments of the present disclosure will now be described more fully hereinafter with reference to the accompanying drawings, in which embodiments of the disclosure are shown. This disclosure may, however, be embodied in different forms and should not be construed as limited to the embodiments set forth herein.

The same reference numbers may indicate the same components throughout the specification.

Features of each of various embodiments of the present disclosure may be partially or entirely combined with each other and may technically variously interwork with each other, and respective embodiments may be implemented independently of each other or may be implemented together in association with each other.

Hereinafter, embodiments will be described with reference to the accompanying drawings.

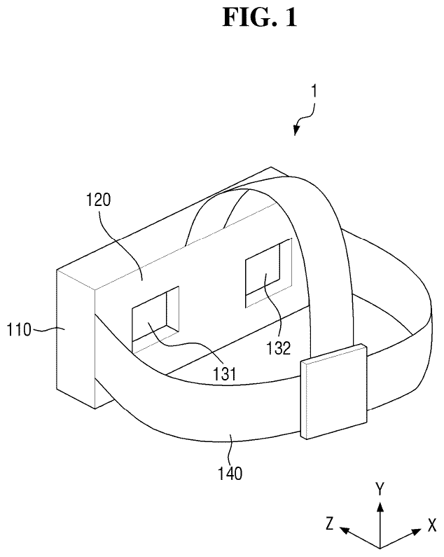

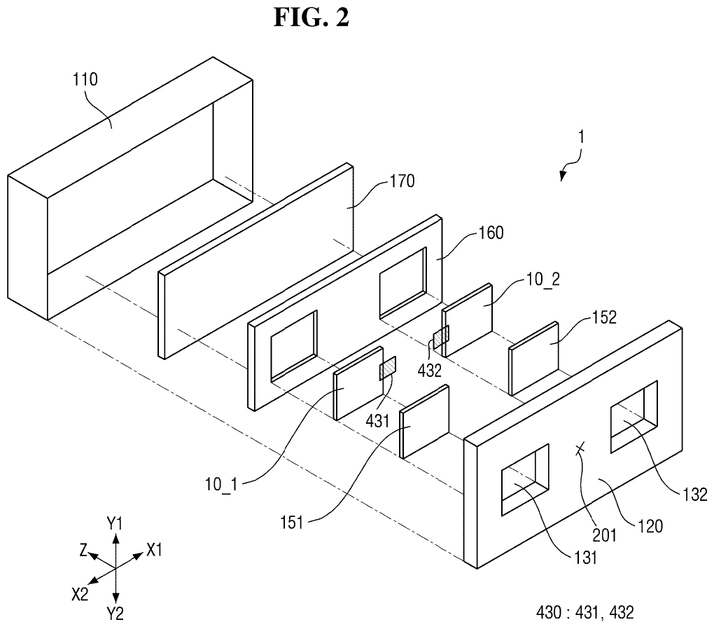

FIG. 1 is a perspective view of a head-mounted display device according to an embodiment of the present disclosure. FIG. 2 is an exploded perspective view of an example of the head-mounted display device of FIG. 1.

Referring to FIGS. 1 and 2, a head-mounted display device 1 according to an embodiment includes a first display device 10_1, a second display device 10_2, a display device housing 110, and a housing cover 120, a first eyepiece 131, a second eyepiece 132, a head strap band 140, a middle frame 160, a first optical member 151, a second optical member 152, and a control circuit board 170, and a connector.

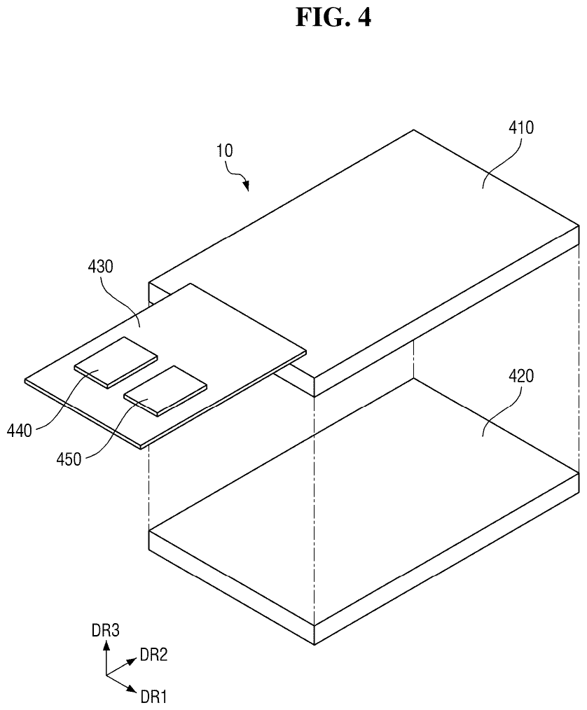

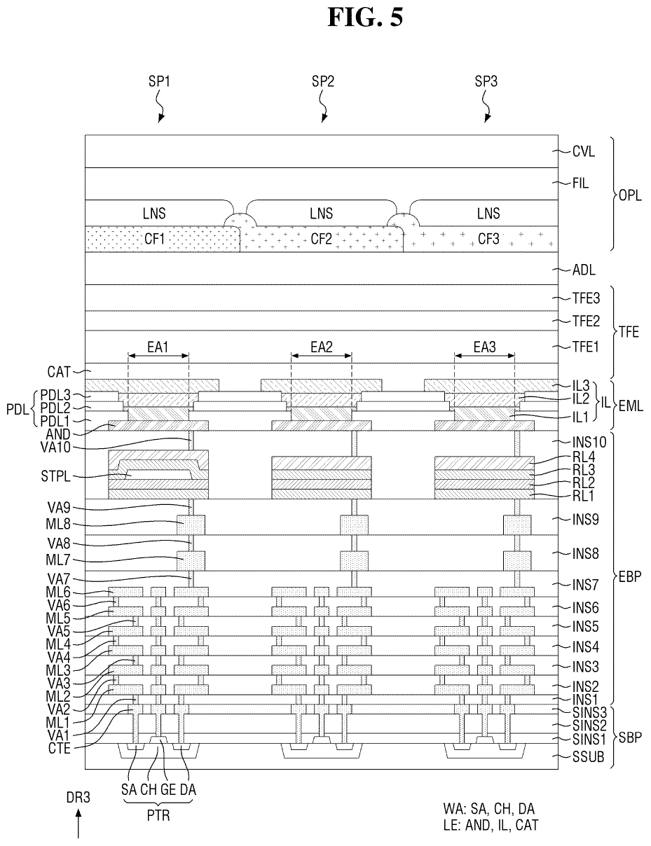

The first display device 10_1 provides images to a user's left eye, and the second display device 10_2 provides images to the user's right eye. Each of the first display device 10_1 and the second display device 10_2 is substantially identical to the display device 10 described with reference to FIGS. 4 and 5.

Therefore, descriptions of the first display device 10_1 and the second display device 10_2 will be replaced with descriptions referring to FIGS. 4 and 5.

The first optical member 151 is disposed between the first display device 10_1 and the first eyepiece 131. The second optical member 152 is disposed between the second display device 10_2 and the second eyepiece 132. Each of the first optical member 151 and the second optical member 152 includes at least one convex lens.

The middle frame 160 is disposed between the first display device 10_1 and the control circuit board 170, and between the second display device 10_2 and the control circuit board 170. The middle frame 160 supports and fixes the first display device 10_1, the second display device 10_2 and the control circuit board 170.

The control circuit board 170 is disposed between the middle frame 160 and the display device housing 110. The control circuit board 170 is connected to the first display device 10_1 and the second display device 10_2 through a connector. The control circuit board 170 converts an externally received image source into digital video data (DATA) and transmits the digital video data (DATA) to the first display device 10_1 and the second display device 10_2 through the connector.

The control circuit board 170 transmits digital video data (DATA) associated with a left-eye image optimized for the user's left eye to the first display device 10_1, and transmits digital video data (DATA) associated with a right eye image optimized for the user's right eye to the second display device 10_2. However, in some embodiments, the control circuit board 170 transmits the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 covers the open face of the housing 110. The housing cover 120 includes the first eyepiece 131 where the user's left eye is placed, and the second eyepiece 132 where the user's right eye is placed. Although the first eyepiece 131 and the second eyepiece 132 are separately disposed in the example shown in FIGS. 1 and 2, embodiments of the present disclosure are not necessarily limited thereto. In some embodiments, first eyepiece 131 and the second eyepiece 132 are combined into a single element.

The first eyepiece 131 is aligned with the first display device 10_1 and the first optical member 151, and the second eyepiece 132 is aligned with the second display device 10_2 and the second optical member 152. Therefore, a user can see virtual images on the first display device 10_1 magnified by the first optical member 151 through the first eyepiece 131, and virtual images on the second display device 10_2 magnified by the second optical member 152 through the second eyepiece 132.

Each of the first display device 10_1 and the second display device 10_2 includes a display panel and a circuit board that includes a driver circuit that drives the display panel, as will be described below. The display panel includes an emission material layer and an optical layer that includes lenses disposed on the emission material layer. For example, the first display device 10_1 includes a first circuit board 431, and the second display device 10_2 includes a second circuit board 432.

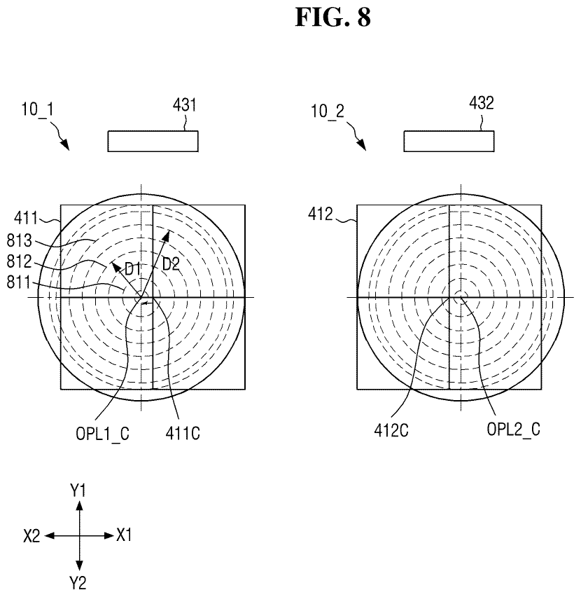

As shown in FIG. 2, the first circuit board 431 of the first display device 10_1 and the second circuit board 432 of the second display device 10_2 are symmetrically arranged with respect to a center 201 of the housing cover 120 located between the first eyepiece 131 and the second eyepiece 132. As the first circuit board 431 and the second circuit board 432 are symmetrically arranged with respect to the center 201 of the housing cover 120, it is possible to use a decenter structure that corrects the location of an optical sweet spot to the display panel of each of the display devices, so that image distortion can be prevented and the fabrication costs can be reduced by a simplified structure. For example, in the first display device 10_1 and the second display device 10_2, the decenter structures used by the display panel to correct the location of the optical sweet spot have substantially the same structure. According to an embodiment, the first display device 10_1 and the second display device 10_2 have substantially the same structure, and the first circuit board 431 and the second circuit board 432 are symmetrically arranged with respect to the center 201 of the housing cover 120, so that the decenter structure has a simplified structure. For example, according to an embodiment, undistorted images can be provided to each of the user's left and right eyes by fabricating a pair of the same display devices 10_1 and 10_2, and thus the first display device 10_1 and the second display device 10_2 need not be differently designed to use a decenter structure. An embodiment of the present disclosure will be described in detail below with reference to FIGS. 8 to 15.

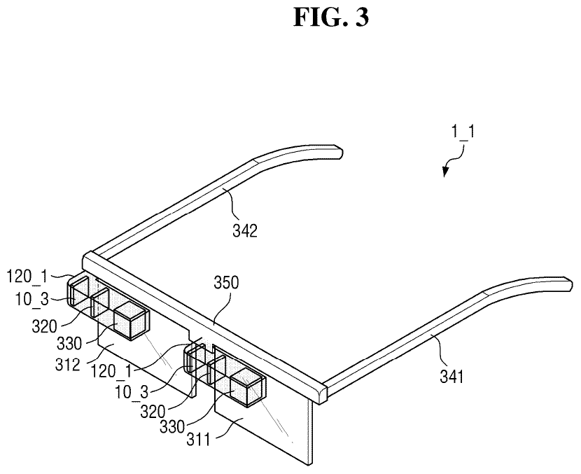

The head strap band 140 fixes the housing 110 to a user's head so that the first eyepiece 131 and the second eyepiece 132 of the housing cover 1210 remain in line with the user's left and right eyes, respectively. By implementing a light and small display device housing 120, the head-mounted display device 1 can include an eyeglasses frame as shown in FIG. 3 instead of a head strap band.

In addition, the head-mounted display device 1 may further include a battery that supplies power, an external memory slot for inserting an external memory, and an external connection port and a wireless communication module that receive an image source. The external connection port is one of a USB (universe serial bus) terminal, a display port, or an HDMI (high-definition multimedia interface) terminal. The wireless communication module is one of a 5G communication module, a 4G communication module, a Wi-Fi module, or a Bluetooth module.

FIG. 3 is a perspective view of a head-mounted display device according to an embodiment of the present disclosure.

Referring to FIG. 3, the head-mounted display device 1_1 according to an embodiment is a glasses-type display device with a light and small display device housing 120_1. The head-mounted display device 1_1 according to an embodiment includes display devices 10_3, a left-eye lens 311, a right-eye lens 312, a support frame 350, eyeglass temples 341 and 342, optical members 320, optical path conversion members 330, and display device housings 120_1.

The display device 10_3 shown in FIG. 3 is substantially identical to the display device 10 described with reference to FIGS. 4 and 5.

The display device housings 1201 are disposed on the right and left sides of the support frame 350. The display device housings 1201 include the display devices 10_3, the optical members 320, and the optical path conversion members 330. The images displayed on the display device 10_3 are enlarged by the optical member 320, and the optical paths of the images are converted by the optical path conversion member 330 to be provided to the user's right eye through the right eye lens 312 and to the user's left eye through the left eye lens 311. As a result, the user can see, with the left eye and the right eye, augmented reality images that combine virtual images displayed on the display device 10_3 and real world images viewed through the left eye lens 311 and the right eye lens 312.

FIG. 4 is an exploded, perspective view of a display device according to an embodiment of the present disclosure.

Referring to FIG. 4, the display device 10 according to the embodiment can display a moving image or a still image. The display device 10 according to an embodiment can be used by a portable electronic device such as a mobile phone, a smart phone, a tablet PC, a mobile communications terminal, an electronic notebook, an electronic book, a portable multimedia player (PMP), a navigation device and a ultra mobile PC (UMPC). For example, the display device 10 is used as a display unit of a television, a laptop computer, a monitor, an electronic billboard, or an Internet of Things (IoT) device. In some embodiments, the display device 10 is incorporated into to a smart watch, a watch phone, or a head-mounted display (HMD) that implements virtual reality and/or augmented reality.

According to an embodiment, the display device 10 includes a display panel 410, a heat dissipation layer 420, a circuit board 430, a driver circuit 440, and a power supply circuit 450.

The display panel 410 has a substantially rectangular shape when viewed from above. For example, the display panel 410 has a substantially rectangular shape that has shorter sides in a first direction DR1 and longer sides in a second direction DR2 that crosses the first direction DR1 when viewed from above. In the display panel 410, the corners where the shorter sides in the first direction DR1 meet the longer sides in the second direction DR2 may be rounded with a predetermined curvature or may be a right angle. The shape of the display panel 410 when viewed from above is not limited to a rectangular shape, and may have, for example, a different polygonal shape, a circular shape, or an elliptical shape. The shape of the display device 10 follows the shape of the display panel 410 when viewed from above, but the embodiments of the present disclosure are not necessarily limited thereto.

The display panel 410 includes a display area where images are displayed, and a non-display area where no image is displayed.

The display area includes a plurality of pixels, and each of the plurality of pixels includes a plurality of sub-pixels SP1, SP2 and SP3 (see FIG. 5). The sub-pixels SP1, SP2 and SP3 include a plurality of pixel transistors. The pixel transistors are formed via a semiconductor process and are disposed on a semiconductor substrate SSUB (see FIG. 5). For example, the pixel transistors are implemented as complementary metal oxide semiconductor (CMOS) transistors.

The heat dissipation layer 420 overlaps the display panel 410 in the third direction DR3, which is a thickness direction of the display panel 410. The heat dissipation layer 420 is disposed on one surface of the display panel 410, such as the rear surface. The heat dissipation layer 420 discharges heat generated in the display panel 410. The heat dissipation layer 420 includes a metal layer having a high thermal conductivity, such as at least one of graphite, silver (Ag), copper (Cu) or aluminum (Al).

The circuit board 430 is electrically connected to a plurality of pads in a pad area of the display panel 410 using a conductive adhesive member such as an anisotropic conductive film. The circuit board 430 may be a flexible printed circuit board made of a flexible material, or a flexible film. Although the circuit board 430 is unfolded in FIG. 4, the circuit board 430 may be bent. When the circuit board 430 is bent, one end of the circuit board 430 is disposed on the rear surface of the display panel 410. The one end of the circuit board 430 is opposite to an opposite end of the circuit board 430 that is connected to the pads in the pad area of the display panel 410.

The driver circuit 440 receives digital video data and timing signals from an external source. The driver circuit 440 generates a scan timing control signal, an emission timing control signal, and a data timing control signal that control the display panel 410 in response to the timing signals.

The power supply circuit 450 generates a plurality of panel driving voltages in response to a supply voltage received from an external source. For example, the power supply circuit 450 generates a first supply voltage, a second supply voltage, and a third supply voltage and transmits them to the display panel 410.

Each of the driver circuit 440 and the power supply circuit 450 can be implemented as an integrated circuit (IC) and attached to a surface of the circuit board 430.

FIG. 5 is a cross-sectional view of a part of a display panel according to an embodiment of the present disclosure. For example, FIG. 5 shows a cross-sectional structure of a part of a display area that includes a plurality of sub-pixels SP1, SP2 and SP3.

Referring to FIG. 5, in an embodiment, the display panel 410 includes a semiconductor backplane SBP, an emission material backplane EBP, an emission material layer EML, an encapsulation layer TFE, an optical layer OPL, a cover layer CVL, and a polarizer.

The semiconductor backplane SBP includes a semiconductor substrate SSUB that includes a plurality of pixel transistors PTR, a plurality of semiconductor insulating films that cover the plurality of pixel transistors PTR, and a plurality of contact terminals CTE that are electrically connected to the pixel transistors PTR.

The semiconductor substrate SSUB may be a silicon substrate, a germanium substrate, or a silicon-germanium substrate. The semiconductor substrate SSUB is doped with first-type impurities. A plurality of well areas WA are located in the upper surface of the semiconductor substrate SSUB. The well areas WA are doped with second-type impurities. The second-type impurities differ from the first-type impurities. For example, when the first-type impurities are p-type impurities, the second-type impurities are n-type impurities, and when the first-type impurities are n-type impurities, the second-type impurities are p-type impurities.

Each of the well areas WA includes a source region SA associated with a source electrode of a pixel transistor PTR, a drain region DA associated with a drain electrode thereof, and a channel region CH between the source region SA and the drain region DA.

Each of the source region SA and the drain region DA is doped with the second-type impurities. The gate electrode GE of the pixel transistor PTR overlaps the well area WA in the third direction DR3. The channel region CH overlaps the gate electrode GE in the third direction DR3. The source region SA is located on one side of the gate electrode GE, and the drain region SA is located on the opposite side of the gate electrode GE.

Each of the plurality of well areas WA further includes a first low-concentration impurity region disposed between the channel region CH and the source region SA, and a second low-concentration impurity region disposed between the channel region CH and the drain region DA. The first low-concentration impurity region has a lower impurity concentration than the source region SA. The second low-concentration impurity region has a lower impurity concentration than the drain region DA. The distance between the source region SA and the drain region DA is increased by the first low-concentration impurity region and the second low-concentration impurity region. Therefore, the length of the channel region CH of each of the pixel transistors PTR can be increased, which can prevent a punch-through and a hot carrier phenomenon due to a short channel.

A first semiconductor insulating film SINS1 is disposed on the semiconductor substrate SSUB. The first semiconductor insulating film SINS1 covers the plurality of pixel transistors PTR. The first semiconductor insulating film SINS1 may be formed of, but is not necessarily limited to, one of a silicon carbon nitride (SiCN) or a silicon oxide (SiOx)-based inorganic film.

A second semiconductor insulating film SINS2 is disposed on the first semiconductor insulating film SINS1. The second semiconductor insulating film SINS2 may be formed of a silicon oxide (SiOx)-based inorganic film, but embodiments of the present disclosure are not necessarily limited thereto.

A plurality of contact terminals CTE are disposed on the second semiconductor insulating film SINS2. Each of the plurality of contact terminals CTE is connected to one of the gate electrode GE, the region SA or the drain region DA of each of the pixel transistors PTR through a hole that penetrates the first semiconductor insulating film SINS1 and the second semiconductor insulating film INS2. The contact terminals CTE are formed of one of copper (Cu), aluminum (Al), tungsten (W), molybdenum (Mo), chromium (Cr), gold (Au), titanium (Ti), nickel (Ni) or neodymium (Nd), or an alloy thereof.

A third semiconductor insulating film SINS3 is disposed on the second semiconductor insulating film SINS2 and the side surfaces of each of the contact terminals CTE. The upper surface of each of the contact terminals CTE is not covered by the third semiconductor insulating film SINS3 but is exposed. The third semiconductor insulating film SINS3 is formed of a silicon oxide (SiOx)-based inorganic film, but embodiments of the present disclosure are not necessarily limited thereto.

The semiconductor substrate SSUB may be replaced with a glass substrate or a polymer resin substrate such as polyimide. For example, thin-film transistors are disposed on a glass substrate or a polymer resin substrate. A glass substrate is a rigid substrate that is not bent, while a polymer resin substrate is a flexible substrate that can be bent or curved.

The emission material backplane EBP includes first to eighth metal layers ML1 to ML8, reflective metal layers RL1 to RL4, a plurality of vias VA1 to VA10, and a step layer STPL. In addition, the emission material backplane EBP includes a plurality of interlayer dielectric films INS1 to INS10 disposed between the first to sixth metal layers ML1 to ML8 and between the reflective metal layers RL1 to RL4.

The first to eighth metal layers ML1 to ML8 implement a circuit of a first sub-pixel SP1 by connecting a plurality of exposed contact terminals CTE in the semiconductor backplane SBP. For example, the transistors of the sub-pixel circuit are formed in the semiconductor backplane SBP, and the connection of the transistors and the capacitors of the sub-pixel circuit are made through the first to eighth metal layers ML1 to ML8. In addition, the connection between the drain region that corresponds to the drain electrode of one of the transistors, the source region that corresponds to the source electrode of another transistor, and the first electrode of a light-emitting element is also made through the first to eighth metal layers ML1 to ML8.

The first interlayer insulating film INS1 is disposed on the semiconductor backplane SBP. Each of the first vias VA1 penetrates the first interlayer dielectric film INS1 and is connected to the exposed contact terminal CTE. Each of the first metal layers ML1 is disposed on the first interlayer insulating film INS1 and is connected to the first via VA1.

The second interlayer dielectric film INS2 is disposed on the first interlayer dielectric film INS1 and the first metal layers ML1. Each of the second vias VA2 penetrates through the second interlayer dielectric film INS2 and is connected to the exposed first metal layer ML1. Each of the second metal layers ML2 is disposed on the second interlayer insulating film INS2 and is connected to the second via VA2.

The third interlayer dielectric film INS3 is disposed on the second interlayer dielectric film INS2 and the second metal layers ML2. Each of the third vias VA3 penetrates through the third interlayer dielectric film INS3 and is connected to the exposed second metal layer ML2. Each of the third metal layers ML3 is disposed on the third interlayer insulating film INS3 and is connected to the third via VA3.

The fourth interlayer dielectric film INS4 is disposed on the third interlayer dielectric film INS3 and the third metal layers ML3. Each of the fourth vias VA2 penetrates through the fourth interlayer dielectric film INS4 and is connected to the exposed third metal layer ML3. Each of the fourth metal layers ML4 is disposed on the fourth interlayer insulating film INS4 and is connected to the fourth via VA4.

The fifth interlayer dielectric film INS5 is disposed on the fourth interlayer dielectric film INS4 and the fourth metal layers ML4. Each of the fifth vias VA5 penetrates through the fifth interlayer dielectric film INS5 and is connected to the exposed fourth metal layer ML4. Each of the fifth metal layers ML5 is disposed on the fifth interlayer insulating film INS5 and is connected to the fifth via VA5.

The sixth interlayer dielectric film INS6 is disposed on the fifth interlayer dielectric film INS5 and the fifth metal layers ML5. Each of the sixth vias VA6 penetrates through the sixth interlayer dielectric film INS6 and is connected to the exposed fifth metal layer ML5. Each of the sixth metal layers ML6 is disposed on the sixth interlayer insulating film INS6 and is connected to the sixth via VA6.

The seventh interlayer dielectric film INS7 is disposed on the sixth interlayer dielectric film INS6 and the sixth metal layers ML6. Each of the seventh vias VA7 penetrates through the seventh interlayer dielectric film INS7 and is connected to the exposed sixth metal layer ML6. Each of the seventh metal layers ML7 is disposed on the seventh interlayer insulating film INS7 and is connected to the seventh via VA7.

The eighth interlayer dielectric film INS8 is disposed on the seventh interlayer dielectric film INS7 and the seventh metal layers ML7. Each of the eighth vias VA8 penetrates through the eighth interlayer dielectric film INS8 and is connected to the exposed seventh metal layer ML7. Each of the eighth metal layers ML8 is disposed on the eighth interlayer insulating film INS8 and is connected to the eighth via VA8.

The first to eighth metal layers ML1 to ML8 and the first to eighth vias VA1 to VA8 are made of substantially the same material. The first to eighth metal layers ML1 to ML8 and the first to eighth vias VA1 to VA8 are made of one of copper (Cu), aluminum (Al), tungsten (W), molybdenum (Mo), chromium (Cr), gold (Au), titanium (Ti), nickel (Ni) or neodymium (Nd), or an alloy thereof. The first to eighth vias VA1 to VA8 are made of substantially the same material. The first to eighth interlayer dielectric films INS1 to ILD8 are formed of a silicon oxide (SiOx)-based inorganic film, but embodiments of the present specification are not necessarily limited thereto.

The thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6 are greater than the thickness of the first via VA1, the thickness of the second via VA2, the thickness of the third via VA3, the thickness of the fourth via VA4, the thickness of the fifth via VA5 and the thickness of the sixth via VA6. The thickness of the second metal layer ML2, the thickness of the third metal layer ML3, the thickness of the fourth metal layer ML4, the thickness of the fifth metal layer ML5, and the thickness of the sixth metal layer ML6 are greater than the thickness of the first metal layer ML1. The thickness of the second metal layer ML2, the thickness of the third metal layer ML3, the thickness of the fourth metal layer ML4, the thickness of the fifth metal layer ML5 and the thickness of the sixth metal layer ML6 are substantially all equal.

The thickness of the seventh metal layer ML7 and the thickness of the eighth metal layer ML8 are greater than the thicknesses of each of the first metal layer to the sixth metal layer ML1, ML2, ML3, M14, ML5 and ML6. The thickness of the seventh metal layer ML7 and the thickness of the eighth metal layer ML8 are greater than the thickness of the seventh via VA7 and the thickness of the eighth via VA8. The thickness of the seventh via VA7 and the thickness of the eighth via VA8 are greater than the thicknesses of each of the first via to the sixth via VA1, VA2, VA3, VA4, VA5 and VA6. The thickness of the seventh metal layer ML7 is substantially equal to the thickness of the eighth metal layer ML8.

The ninth interlayer dielectric film INS9 is disposed on the eighth interlayer dielectric film INS8 and the eighth metal layers ML8. The ninth interlayer dielectric film INS9 is formed of a silicon oxide (SiOx)-based inorganic film, but embodiments of the present disclosure are not necessarily limited thereto.

Each of the ninth vias VA9 penetrates through the ninth interlayer dielectric film INS9 and is connected to the exposed eighth metal layer ML8. The ninth vias VA9 are made of one of copper (Cu), aluminum (Al), tungsten (W), molybdenum (Mo), chromium (Cr), gold (Au), titanium (Ti), nickel (Ni) or neodymium (Nd), or an alloy thereof.

The first reflective electrodes RL1 are disposed on the ninth interlayer dielectric film INS9 and are connected to the ninth via VA9. The first reflective electrodes RL1 are made of one of copper (Cu), aluminum (Al), tungsten (W), molybdenum (Mo), chromium (Cr), gold (Au), titanium (Ti), nickel (Ni) or neodymium (Nd), or an alloy thereof.

The second reflective electrodes RL2 is disposed on the first reflective electrodes RL1. The second reflective electrodes RL2 is made of one of copper (Cu), aluminum (Al), tungsten (W), molybdenum (Mo), chromium (Cr), gold (Au), titanium (Ti), nickel (Ni) or neodymium (Nd), or an alloy thereof. For example, the second reflective electrodes RL2 include titanium nitride (TiN).

In the first sub-pixel SP1, a step layer STPL is disposed on the second reflective electrode RL2. No step layer STPL is disposed in each of the second sub-pixel SP2 and the third sub-pixel SP3. The thickness of the step layer STPL is determined based on the wavelength of the light of a first color and the distance from a first emissive layer to a fourth reflective electrode RL4 so that the light of the first color emitted from the first emissive layer of the first sub-pixel SP1 is reflected. The step layer STPL is formed of, but is not limited to, a silicon carbon nitride (SiCN) or a silicon oxide (SiOx)-based inorganic film.

In the first sub-pixel SP1, the third reflective electrode RL3 is disposed on the second reflective electrode RL2 and the step layer STPL. In the second sub-pixel SP2 and the third sub-pixel SP3, the third reflective electrode RL3 is disposed on the second reflective electrode RL2. The third reflective electrodes RL3 is made of one of copper (Cu), aluminum (Al), tungsten (W), molybdenum (Mo), chromium (Cr), gold (Au), titanium (Ti), nickel (Ni) or neodymium (Nd), or an alloy thereof.

In an embodiment, at least one of the first reflective electrode RL1, the second reflective electrode RL2 or the third reflective electrode RL3 can be eliminated.

The fourth reflective electrodes RL4 is disposed on the third reflective electrodes RL3. The fourth reflective electrodes RL4 reflect light from intermediate layers of the first to third sub-pixels SP1, SP2 and SP3. The fourth reflective electrodes RL4 include a highly reflective metal so that light can be reflected. The fourth reflective electrodes RL4 are made of, but not necessarily limited to, aluminum (Al), one of a stack of aluminum and titanium (Ti/Al/Ti), a stack of aluminum and ITO (ITO/Al/ITO), silver (Ag), palladium (Pd), an APC alloy, which is an alloy of copper (Cu), or a stack of an APC alloy and ITO (ITO/APC/ITO).

The tenth interlayer dielectric film INS10 is disposed on the ninth interlayer dielectric film INS9 and the fourth reflective electrodes RL4. The tenth interlayer dielectric film INS10 is formed of a silicon oxide (SiOx)-based inorganic film, but embodiments of the present disclosure are not necessarily limited thereto.

Each of the tenth vias VA10 penetrates through the tenth interlayer dielectric film INS10 and is connected to the fourth reflective electrodes RL4. The tenth vias VA10 include one of copper (Cu), aluminum (Al), tungsten (W), molybdenum (Mo), chromium (Cr), gold (Au), titanium (Ti), nickel (Ni) or neodymium (Nd), or an alloy thereof. Due to the step layer STPL, the thickness of the tenth via VA10 in the first sub-pixel SP1 is less than the thickness of the tenth via VA10 in each of the second sub-pixel SP2 and the third sub-pixel SP3.

The emission material layer EML is disposed on the emission material backplane EBP. The emission material layer EML includes light-emitting elements LE that each include a first electrode AND, an intermediate layer IL and a second electrode CAT, and a pixel-defining film PDL.

The first electrode AND of each of the light-emitting elements LE is disposed on the tenth interlayer dielectric film INS10 and is connected to the tenth via VA10. The first electrode AND of each of the light-emitting elements LE is connected to one of the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8 and the contact terminals CTE. The first electrode AND of each of the light-emitting elements LE includes one of copper (Cu), aluminum (Al), tungsten (W), molybdenum (Mo), chromium (Cr), gold (Au), titanium (Ti), nickel (Ni) or neodymium (Nd), or an alloy thereof. For example, the first electrode AND of each of the light-emitting elements LE includes titanium nitride (TiN).

The pixel-defining film PDL is partially disposed on the first electrode AND of each of the light-emitting elements LE. The pixel-defining film PDL covers the edge of the first electrode AND of each of the light-emitting elements LE. The pixel-defining film PDL partitions the first emission areas EA1, the second emission areas EA2 and the third emission areas EA3.

A first emission area EA1 is an area in the first sub-pixel SP1 where the first electrode AND, the intermediate layer IL and the second electrode CAT are sequentially stacked on one another to emit light. A second emission area EA2 is an area in the second sub-pixel SP2 where the first electrode AND, the intermediate layer IL and the second electrode CAT are sequentially stacked on one another to emit light. A third emission area EA3 is an area in the third sub-pixel SP3 where the first electrode AND, the intermediate layer IL and the second electrode CAT are sequentially stacked on one another to emit light.

The pixel-defining film PDL includes first to third pixel-defining films PDL1, PDL2 and PDL3. The first pixel-defining film PDL1 is disposed on the edge of the first electrode AND of each of the light-emitting elements LE, the second pixel-defining film PDL2 is disposed on the first pixel-defining film PDL1, and the third pixel-defining film PDL3 is disposed on the second pixel-defining film PDL2. The first pixel-defining film PDL1, the second pixel-defining film PDL2 and the third pixel-defining film PDL3 includes a silicon oxide (SiOx)-based inorganic film, but embodiments of the present disclosure are not necessarily limited thereto.

The intermediate layer IL includes a first intermediate layer IL1, a second intermediate layer IL2, and a third intermediate layer IL3.

The intermediate layer IL has a tandem structure that includes a plurality of intermediate layers IL1, IL2 and IL3 that emit different color light. For example, the intermediate layer IL includes the first intermediate layer IL1 that emits light of the first color, the second intermediate layer IL2 that emits light of a second color, and the third intermediate layer IL3 that emits light of a third color. The first intermediate layer IL1, the second intermediate layer IL2 and the third intermediate layer IL3 are sequentially stacked on one another.

The first intermediate layer IL1 has a structure that includes first hole transport layer, a first organic emissive layer that emits light of the first color, and a first electron transport layer sequentially stacked on one another. The second intermediate layer IL2 has a structure that includes a second hole transport layer, a second organic emissive layer that emits light of the second color, and a second electron transport layer sequentially stacked on one another. The third intermediate layer IL3 has a structure that includes a third hole transport layer, a third organic emissive layer that emits light of the third color, and a third electron transport layer sequentially stacked on one another.

The intermediate layer IL covers the first electrode AND at an opening of the pixel-defining film PDL, covers the pixel-defining film PDL between adjacent sub-pixels SP1, SP2 and SP3, and is partially disconnected.

According to an embodiment, a leakage current between adjacent sub-pixel SP1, SP2 and SP3 can be prevented, and color crosstalk can be prevented, by disconnecting the intermediate layer IL between the adjacent sub-pixel SP1, SP2 and SP3. Color crosstalk refers to, for example, a phenomenon that a red sub-pixel adjacent to a blue sub-pixel is unintentionally turned on when the blue sub-pixel emits blue light. Since color crosstalk occurs due to leakage current, it can occur if a blue sub-pixel and a red sub-pixel are adjacent to each other, which have a large difference in driving voltages. For example, when a driving current is supplied to the light-emitting element of a blue sub-pixel to turn on the blue sub-pixel, a part of the driving current may be transmitted to a red sub-pixel through at least some conductive layers of the intermediate IL, which is leakage current. If leakage current is generated, the red sub-pixel may be unintentionally turned on when the blue sub-pixel is turned on.

The number of intermediate layers IL1, IL2 and IL3 that emit different color light is not limited to that shown in FIG. 5. For example, in some embodiments, the intermediate layer IL includes two intermediate layers. For example, one of the two intermediate layers is substantially identical to the first intermediate layer IL1, and the other includes a second hole transport layer, a second organic emissive layer, a third organic emissive layer, and a second electron transport layer. For example, a charge generation layer is disposed between the two intermediate layers to supply electrons to one intermediate layer and to supply charges to the other intermediate layer.

In addition, although the first to third intermediate layers IL1, IL2 and IL3 are all disposed in the first emission area EA1, the second emission area EA2 and the third emission area EA3 in FIG. 5, embodiments of the present disclosure are not necessarily limited thereto. For example, in some embodiments, the first intermediate layer IL1 is disposed in the first emission area EA1 but not in the second emission area EA2 and the third emission area EA3. In addition, in some embodiments, the second intermediate layer IL2 is disposed in the second emission area EA2 but not in the first emission area EA1 and the third emission area EA3. In addition, in some embodiments, the third intermediate layer IL3 is disposed in the third emission area EA3 but not in the first emission area EA1 and the second emission area EA2. For example, the first to third color filters CF1, CF2 and CF3 of the optical layer OPL can be eliminated.

The second electrode CAT is disposed on the third intermediate layer IL3. The second electrode CAT includes a transparent conductive material (TCP) such as ITO or IZO that can transmit light, or a semi-transmissive conductive material such as magnesium (Mg), silver (Ag) or an alloy of magnesium (Mg) and silver (Ag). When the second electrode CAT is formed of a semi-transmissive conductive material, the light extraction efficiency is increased by using microcavities in each of the first to third sub-pixels SP1, SP2 and SP3.

The encapsulation layer TFE is disposed on the emission material layer EML. The encapsulation layer TFE includes one or more inorganic films TFE1 and TFE3 that prevent permeation of oxygen or moisture into the emission material layer EML. In addition, the encapsulation layer ENC includes at least one organic film that protects the emission material layer EML from particles such as dust. For example, the encapsulation layer ENC may include a first inorganic encapsulation film TFE1, an organic encapsulation film TFE2 and a second inorganic encapsulation film TFE3.

The first inorganic encapsulation film TFE1 is disposed on the second electrode CAT, the organic encapsulation film TFE2 is disposed on the first inorganic encapsulation film TFE1, and the second inorganic encapsulation film TFE3 is disposed on the organic encapsulation film TFE2. The first inorganic encapsulation film TFE1 and the second inorganic encapsulation film TFE3 each include multiple inorganic layers that include one or more of a silicon nitride layer (SiNx), a silicon oxynitride layer (SiON), a silicon oxide layer (SiOx), a titanium oxide layer (TiOx) or an aluminum oxide layer (AlOx) alternately stacked on one another. The organic encapsulation film TFE2 is a monomer. However, in some embodiments, the organic encapsulation film TFE2 includes at least one of an acryl resin, an epoxy resin, a phenolic resin, a polyamide resin, or a polyimide resin, etc.

An adhesive layer ADL adheres the encapsulation layer TFE to the optical layer OPL. The adhesive layer ADL is a double-sided adhesive member. In addition, the adhesive layer ADL is a transparent adhesive member such as a transparent adhesive or a transparent adhesive resin.

The optical layer OPL includes a plurality of color filters CF1, CF2 and CF3, a plurality of lenses LNS, and a filling layer FIL. The plurality of color filters CF1, CF2 and CF3 include first to third color filters CF1, CF2 and CF3. The first to third color filters CF1, CF2 and CF3 are disposed on the adhesive layer ADL.

The first color filter CF1 is aligned with the first emission area EA1 of the first sub-pixel SP1. The first color filter CF1 transmits light of the first color, such as light in the blue wavelength range. The blue wavelength range is approximately 370 nm to 460 nm. Therefore, the first color filter CF1 transmits light of the first color of the light emitted from the first emission area EA1.

The second color filter CF2 is aligned with the second emission area EA2 of the second sub-pixel SP2. The second color filter CF2 transmits light of the second color, such as light in the green wavelength range. The green wavelength range is approximately 480 nm to 560 nm. Therefore, the second color filter CF2 transmits light of the second color of the light emitted from the second emission area EA2.

The third color filter CF3 is aligned with the third emission area EA3 of the third sub-pixel SP3. The third color filter CF3 transmits light of the third color, such as light in the red wavelength range. The red wavelength range is approximately 600 nm to 750 nm. Therefore, the third color filter CF3 transmits light of the third color of the light emitted from the third emission area EA3.

The lenses LNS are disposed on the first color filter CF1, the second color filter CF2 and the third color filter CF3. Each of the lenses LNS increases a ratio of light directed to the front side of the display device 10. Each of the lenses LNS has a cross-sectional shape that is convex upward.

The filling layer FIL is disposed on the plurality of lenses LNS. The filling layer FIL has a predetermined refractive index so that light travels in the third direction DR3 at the interface between the plurality of lenses LNS and the filling layer FIL. In addition, the filling layer FIL is a planarization layer. The filling layer FIL includes an organic film that includes at least one of an acryl resin, an epoxy resin, a phenolic resin, a polyamide resin, or a polyimide resin.

The cover layer CVL is disposed on the filling layer FIL. The cover layer CVL is one of a glass substrate or a polymer resin such as a resin. If the cover layer CVL is a glass substrate, it is attached to the filling layer FIL. For example, the filling layer FIL adheres to the cover layer CVL. If the cover layer CVL is a glass substrate, it functions as an encapsulation substrate. If the cover layer CVL is a polymer resin such as a resin, it is applied directly on the filling layer FIL.

A polarizer may be disposed on a surface of the cover layer CVL. The polarizer prevents deterioration of visibility due to reflection of external light. The polarizer includes a linear polarizer and a retardation film. For example, the retardation film is a λ/4 plate (quarter-wave plate), but embodiments of the present disclosure are not necessarily limited thereto. If visibility is sufficiently improved by the first to third color filters CF1, CF2 and CF3 regardless of reflection of external light, the polarizer can be eliminated.

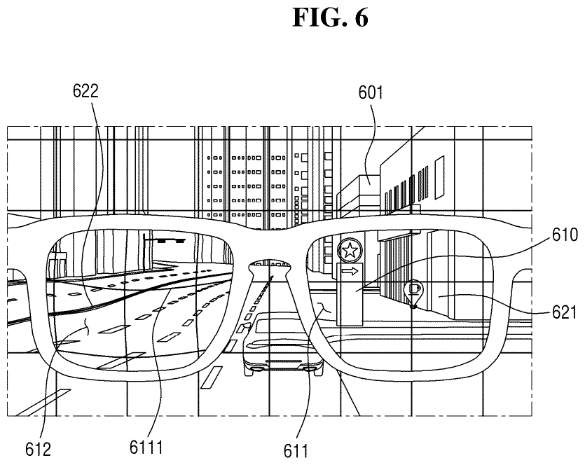

FIG. 6 illustrates image distortion that depends on the location of an optical sweet spot of a lens.

Referring to FIG. 6, in an embodiment, in a display device 610 such as a head-mounted display (HMD) device or AR glasses, a first display device, such as the device 10_1 in FIG. 2, that provides images to the user's left eye is placed on a first eyepiece 611, and a second display device, such as the device 10_2 in FIG. 2, that provides images to the user's right eye is placed on a second eyepiece 612. In FIG. 6, a decenter structure is applied to a lens in the first display device 10_1, whereas no decenter structure is applied to a lens in the second display device 10_2.

The decenter structure corrects the location of an optical sweet spot for the lens, such as the lens LNS of FIG. 5, of the display panel, such as the display panel 410 of FIG. 4. If the decenter structure is not used, the optical sweet spot of the lens is aligned with the center of the display panel 410. When the decenter structure is used, the optical sweet spot of the lens LNS is shifted and aligned by a predetermined distance from the center of the display panel 410. The decenter structure for the lens LNS shifts the optical sweet spot of the lens LNS to an position that prevents image distortion, rather than the geometric center of the lens LNS.

In FIG. 6, a left-eye image 621 is displayed by the first display device 10_1 to provide a real world image 601 captured by a camera to the user's left eye. The left-eye image 621 is provided by the first display device 10_1 that uses a decenter structure.

In FIG. 6, a right-eye image 622 is displayed by the second display device 10_2 to provide a real world image 601 captured by a camera to the user's right eye. The right-eye image 622 is an image provided by the second display device 10_2 that does not use a decenter structure.

Comparing the left-eye image 621 with the right-eye image 622 shown in FIG. 6, the left-eye image 621 provided by the first display device 10_1 that uses the decenter structure has no image distortion. On the contrary, it can be seen that the right-eye image 622 provided by the second display device 10_2 that does not use the decenter structure has image distortion similar to a fisheye effect, as indicated by a virtual grid line 6111. Such image distortion can cause headaches, eye fatigue, and bad eyesight. According to an embodiment, to prevent image distortion as described above, the decenter structure is applied to the lens LNS of the display panel, as will be described below with reference to FIGS. 8 to 15.

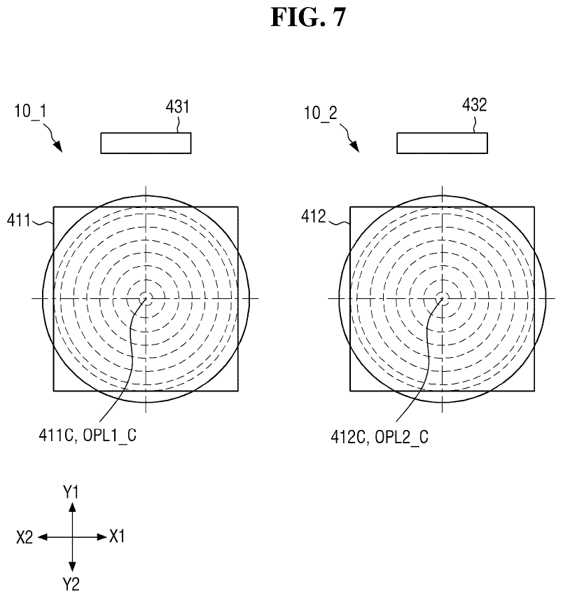

FIG. 7 shows a display device according to a comparative example in which a decenter structure that corrects the location of an optical sweet spot is not applied.

Referring to FIG. 7, a display device according to comparative example includes a first display device 10_1 that provides images to a user's left eye, and a second display device 10_2 that provides images to the user's right eye.

The first display device 10_1 includes a first display panel 411, and a first circuit board 431 that includes a first driver circuit, such as the driver circuit 440 in FIG. 4, that drives the first display panel 411. As described above with reference to FIG. 5, the first display panel 411 includes a first emission material layer EML, such as the layer EML in FIG. 5, and a first optical layer, such as the layer OPL in FIG. 5, that includes first lenses, such as the lenses LNS in FIG. 5, disposed on the first emission material layer. In FIG. 7, circular dashed lines located inside the first display panel 411 indicate the arrangement of the first lenses in the first display panel 411.

The second display device 10_2 includes a second display panel 412, and a second circuit board 432 that includes a second driver circuit, such as the driver circuit 440 in FIG. 4, that drives the second display panel 412. As described above with reference to FIG. 5, the second display panel 412 includes a second emission material layer EML, such as the layer EML in FIG. 5, and a second optical layer, such as the layer OPL in FIG. 5, that includes second lenses, such as the lenses LNS in FIG. 5, disposed on the first emission material layer. In FIG. 7, circular dashed lines located inside the second display panel 412 indicate the arrangement of the second lenses in the second display panel 412.

In a display device according to a comparative example, none of the first display device 10_1 and the second display device 10_2 includes a decenter structure. For example, a center 411C of the first display panel 411 is aligned so that it overlaps a first optical sweet spot OPL1_C of the first optical layer. Accordingly, the center 411C of the first display panel 411 coincides with the first optical sweet spot OPL1_C of the first optical layer when viewed from above. In addition, a center 412C of the second display panel 412 is aligned so that it overlaps a second optical sweet spot OPL2_C of the second optical layer. Accordingly, the center 412C of the second display panel 412 coincides with the second optical sweet spot OPL2_C of the second optical layer when viewed from above.

A display device according to a comparative example has image distortion similar to the fisheye effect, like the right-eye image 612 in FIG. 6, and may cause headaches, eye fatigue, and bad eyesight

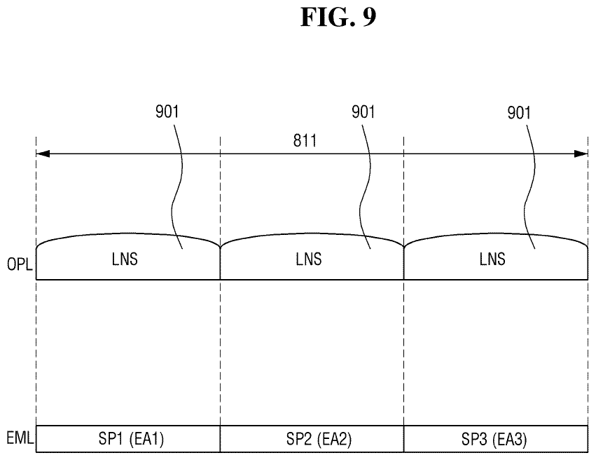

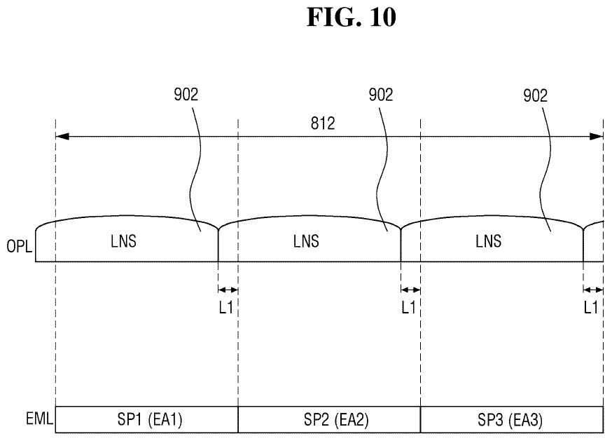

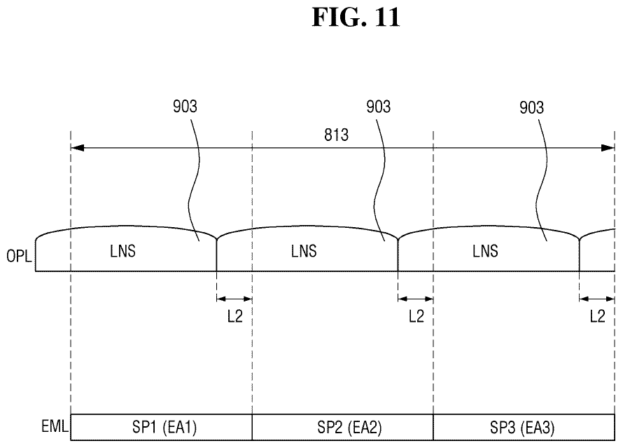

FIG. 8 shows a display device according to an embodiment that uses a decenter structure that corrects the location of an optical sweet spot. FIG. 9 is a cross-sectional view of an alignment of a central lens located at an optical sweet spot and sub-pixels SP1, SP2 and SP3. FIG. 10 is a cross-sectional view of an alignment of a first radius lens located at a first radius distance from an optical sweet spot and sub-pixels SP1, SP2 and SP3. FIG. 11 is a cross-sectional view of an alignment of a second radius lens located at a second radius distance from an optical sweet spot and sub-pixels SP1, SP2 and SP3.

Referring to FIG. 8, a display device according to an embodiment includes a first display device 10_1 that provides images to a user's left eye, and a second display device 10_2 that provides images to the user's right eye.

The first display device 10_1 includes a first display panel 411, and a first circuit board 431 that includes a first driver circuit, such as the driver circuit 440 in FIG. 4, that drives the first display panel 411. As described above with reference to FIG. 5, the first display panel 411 includes a first emission material layer EML, such as the layer EML in FIG. 5, and a first optical layer, such as the layer OPL in FIG. 5, that includes first lenses, such as the lenses LNS in FIG. 5, disposed on the first emission material layer. In FIG. 8, circular dashed lines located inside the first display panel 411 indicate the arrangement of the first lenses in the first display panel 411.

The second display device 10_2 includes a second display panel 412, and a second circuit board 432 that includes a second driver circuit, such as the driver circuit 440 in FIG. 4, that drives the second display panel 412. As described above with reference to FIG. 5, the second display panel 412 includes a second emission material layer EML, such as the layer EML in FIG. 5, and a second optical layer. such as the layer OPL in FIG. 5, that includes second lenses, such as the lenses LNS in FIG. 5, disposed on the first emission material layer. In FIG. 8, circular dashed lines located inside the second display panel 412 indicate the arrangement of the second lenses included in the second display panel 412.

In a display device according to an embodiment, each of the first display device 10_1 and the second display device 10_2 includes a decenter structure. For example, a center 411C of the first display panel 411 does not overlap with a first optical sweet spot OPL1_C of the first optical layer. The first optical sweet spot OPL1_C is shifted from the center 411C of the first display panel 411 by a predetermined distance. For example, the first optical sweet spot OPL1_C is shifted from the center 411C of the first display panel 411 by a predetermined distance in a X2 direction. For example, a center 412C of the second display panel 412 does not overlap with a second optical sweet spot OPL2_C of the second optical layer. The second optical sweet spot OPL2_C is shifted from the center 412C of the second display panel 412 by a predetermined distance. For example, the second optical sweet spot OPL2_C is shifted from the center 412C of the second display panel 412 by a predetermined distance in a X1 direction opposite to the X2 direction. Accordingly, the first lenses of the first optical layer and the second lenses of the second optical layer are symmetrically arranged with respect to the center between the first display device 10_1 and the second display device 10_2, such as the center 201 in FIG. 2.

A display device according to an embodiment can prevent image distortion similar to the fisheye effect, such as that shown in the right-eye image 622 of FIG. 6.

Hereinafter, the alignment of the sub-pixels SP1, SP2 and SP3 of the display panel 410 and the lens LNS according to the shift movement of the optical sweet spot with respect to the center of the first display device 10_1 will be described.

Referring to FIGS. 8 and 9, in an embodiment, of the first lenses, first central lenses 901 that correspond to a periphery 811 of a first optical sweet spot OPL1_C are aligned with the centers of the sub-pixels SP1, SP2 and SP3. The periphery 811 of the first optical sweet spot OPL1_C is a region within a predetermined radius distance from the first optical sweet spot OPL1_C.

Referring to FIGS. 8 and 10, in an embodiment, of the first lenses, the first radius lenses 902 located at the first radius distance D1 from the first optical sweet spot OPL1_C are shifted and aligned by a first distance L1 from the centers of the sub-pixels SP1, SP2 and SP3 of the first emission material layer EML.

Referring to FIGS. 8 and 11, in an embodiment, of the first lenses, the second radius lenses 903 located at a second radius distance D2 greater than the first radius distance D1 from the first optical sweet spot OPL1_C are shifted and aligned by a second distance L2 from the centers of the sub-pixels SP1, SP2 and SP3 of the first emission material layer EML.

The first radius lenses 902 located at the first radius distance D1 from the first optical sweet spot OPL1_C and the second radius lenses 903 located at a second radius distance D2 from the first optical sweet spot OPL1_C may be referred to as peripheral lenses. For example, the first lenses disposed in the first display device 10_1 include a first central lens 901 disposed in the periphery of the first optical sweet spot OPL1_C, and first peripheral lenses 902 and 903 disposed outside the first central lens 901. In addition, the first peripheral lenses 902 and 903 include a first radius lens 902, a second radius lens 902 and a third radius lens, depending on the distance from the first optical sweet spot OPL1_C. The distance by which the first peripheral lenses 902 and 903 are shifted from the centers of the sub-pixels SP1, SP2 and SP3 increases in proportion to the distance from the first optical sweet spot OPL1_C.

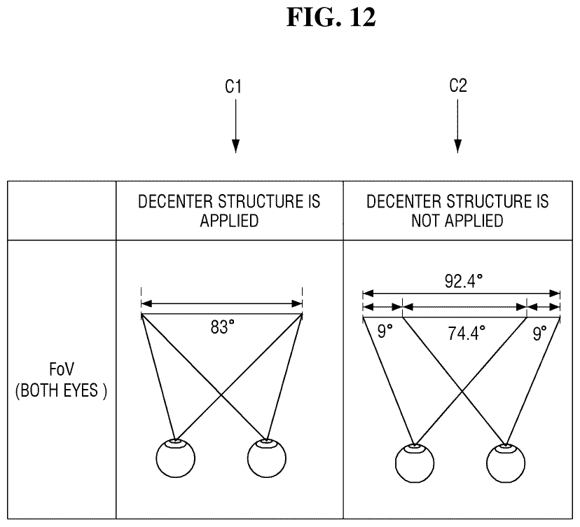

FIG. 12 compares a user's field of views (FoV) with and without a decenter structure that corrects the location of the optical sweet spot.

Referring to FIG. 12, in an embodiment, the user's field of view (FoV) can be expanded by using the decenter structure that corrects the location of the optical sweet spot.

In the table shown in FIG. 12, the first column C1 represents the user's field of view (FoV) when no decenter structure is applied to the first display device 10_1 or the second display device 10_2. As shown in the drawing, the user's field of view FoV is approximately 83 degrees when no decenter structure is applied to the first display device 10_1 or the second display device 10_2.

In the table shown in FIG. 12, the second column C2 represents the user's field of view (FoV) when a decenter structure is applied to each of the first display device 10_1 and the second display device 10_2. As shown in the drawing, the user's field of view FoV is approximately 92.4 degrees when the decenter structure is applied to each of the first display device 10_1 and the second display device 10_2. Accordingly, images with a wide field of view FoV can be provided to users by using the decenter structure with each of the first display device 10_1 and the second display device 10_2.

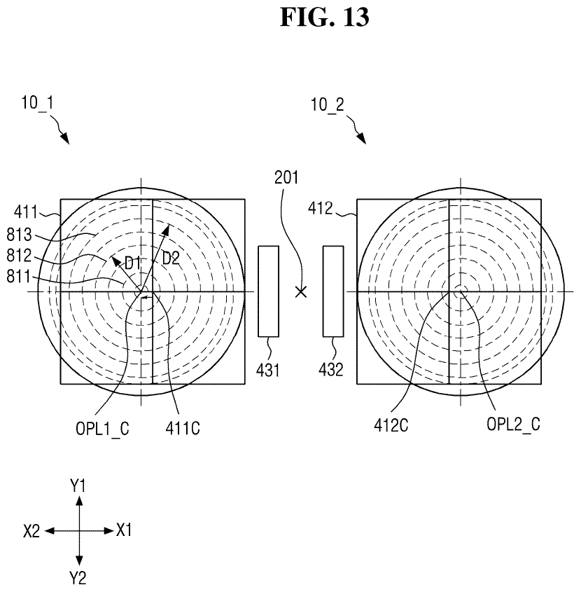

FIGS. 13 to 15 show a variety of embodiments in which a circuit board of a first display device 10_1 and a circuit board of a second display device 10_2 are arranged symmetrically.

According to an embodiment of FIG. 8, the first display device 10_1 should be fabricated so that a first optical sweet spot OPL1_C is shifted and aligned by a predetermined distance from the center 411C of the first display panel 411 in the X2 direction, and the second display device 10_2 should be fabricated so that a second optical sweet spot OPL2_C is shifted and aligned by a predetermined distance from the center 412C of the second display panel 412 in the X1 direction opposite to the X2 direction. Therefore, according to the embodiment of FIG. 8, the first display device 10_1 and the second display device 10_2 should be fabricated separately, which can increase the cost.

According to an embodiment of the present disclosure, images can be provided without distortion to each of the user's left and right eyes by fabricating a pair of the same display devices 10_1 and 10_2, without designing the first display device 10_1 and the second display device 10_2 differently. To this end, according to an embodiment of the present disclosure, a first display device 10_1 and a second display device 10_2 that have the same structure are prepared and are arranged as shown in FIGS. 13 to 15.

According to the embodiment of FIG. 8, the first driver circuit, such as the first circuit board 431, of the first display device 10_1 is disposed in the Y1 direction from the first display panel 411, and, likewise, the second driver circuit, such as the second circuit board 432, of the second display device 10_2 is disposed in the Y1 direction from the second display panel 412. Therefore, according to an embodiment of FIG. 8 where the first driver circuit is disposed in the Y1 direction from the first display panel 411, the first optical sweet spot OPL1_C of the first display panel 411 is shifted and aligned in the X2 direction. In addition, according to an embodiment of FIG. 8 where the second driver circuit is disposed in the Y1 direction from the second display panel 412, the second optical sweet spot OPL2_C of the second display panel 412 is shifted and aligned in the X1 direction opposite to the X2 direction.

According to embodiments of the present disclosure, as shown in FIGS. 13 to 15, the first driver circuit, such as the first circuit board 431, and the second driver circuit, such as the second circuit board 432, are symmetrically arranged with respect to the center 201 of the housing cover 120, considering that the direction in which the first optical sweet spot OPL1_C is shifted and aligned is opposite to the direction in which the second optical sweet spot OPL2_C is shifted and aligned. Accordingly, even though the first display device 10_1 and the second display device 10_2 are fabricated to have substantially the same structure, the first driver circuit and the second driver circuit are symmetrically arranged with respect to the center 201 of the housing cover 120, so that undistorted images can be provided to each of the user's left and right eyes. Hereinafter, each of FIGS. 13 to 15 will be described in more detail.

Referring to FIG. 13, in an embodiment, a first display device 10_1 includes a first display panel 411 that includes a first emission material layer and a first optical layer, and a first circuit board 431 disposed in the first direction X1 from the first display panel 411. A second display device 10_2 includes a second display panel 412 that includes a second emission material layer and a second optical layer, and a second circuit board 432 disposed in the second direction X2 from the second display panel 412.

The first circuit board 431 of the first display device 101 is disposed in a first space of the display device housing 110 (see FIG. 2) located in the first direction X1 from the first eyepiece 131 (see FIG. 2). The second circuit board 432 of the second display device 10_2 is disposed in a second space of the display device housing 110 located from the second eyepiece 132 (see FIG. 2) in the second direction X2 opposite to the first direction XL.

The first lenses of the first optical layer and the second lenses of the second optical layer are symmetrically arranged with respect to the center 201 of the housing cover 120.

The first optical sweet spot OP of the first optical layer is shifted from the center 411C of the first display panel 411 in the second direction X2.

The second optical sweet spot OPL2_C of the second optical layer is shifted from the center 412C of the second display panel 412 in a first direction X1 opposite to the second direction X2.

According to an embodiment of FIG. 13, the first direction X1 is directed from the first display panel 411 toward the center 201 of the housing cover 120. The second direction X2 is directed from the second display panel 412 toward the center 201 of the housing cover 120. The second direction X2 is opposite to the first direction X1. The first direction X1 is opposite to the second direction X2.

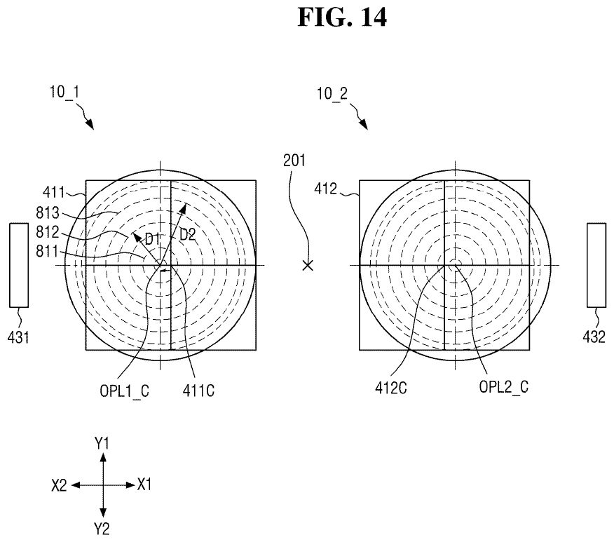

Referring to FIG. 14, in an embodiment, a first display device 10_1 includes a first display panel 411 that includes a first emission material layer and a first optical layer, and a first circuit board 431 disposed in the second direction X2 from the first display panel 411. A second display device 10_2 includes a second display panel 412 that includes a second emission material layer and a second optical layer, and a second circuit board 432 disposed in the first direction X1 from the second display panel 412.

The first circuit board 431 of the first display device 101 is disposed in a first space of the display device housing 110 (see FIG. 2) located in the second direction X2 from the first eyepiece 131 (see FIG. 2). The second circuit board 432 of the second display device 10_2 is disposed in a second space of the display device housing 110 located from the second eyepiece 132 (see FIG. 2) in the first direction X1 opposite to the second direction X2.

The first lenses of the first optical layer and the second lenses of the second optical layer are symmetrically arranged with respect to the center 201 of the housing cover 120.

The first optical sweet spot OPL1_C of the first optical layer is shifted from the center 411C of the first display panel 411 in the second direction X2.

The second optical sweet spot OPL2_C of the second optical layer is shifted from the center 412C of the second display panel 412 in a first direction X1 opposite to the second direction X2.

According to an embodiment of FIG. 14, the second direction X2 is directed from the center 201 of the housing cover 120 toward the first display panel 411. The first direction X1 is directed from the center 201 of the housing cover 120 toward the second display panel 412.

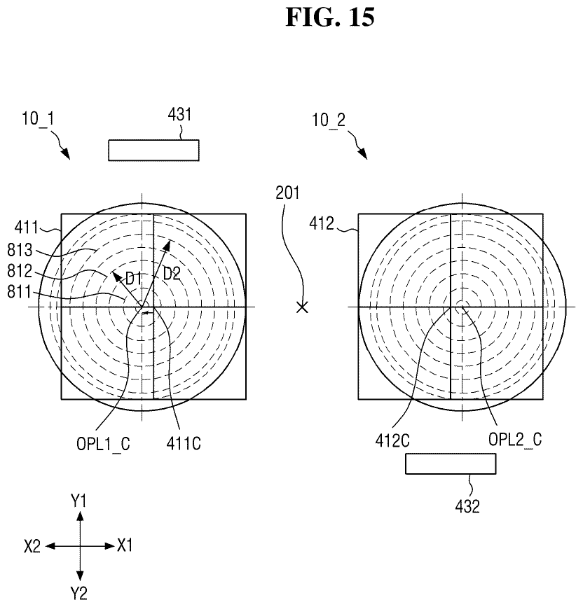

Referring to FIG. 15, a first display device 10_1 includes a first display panel 411 that includes a first emission material layer and a first optical layer, and a first circuit board 431 disposed in a third direction Y1 from the first display panel 411. A second display device 10_2 includes a second display panel 412 that includes a second emission material layer and a second optical layer, and a second circuit board 432 disposed in a fourth direction Y2 from the second display panel 412.

The first circuit board 431 of the first display device 101 is disposed in a first space of the display device housing 110 located in the third direction Y1 from the first eyepiece 131. The second circuit board 432 of the second display device 10_2 is disposed in a second space of the display device housing 110 located from the second eyepiece 132 in the fourth direction Y2 opposite to the third direction Y1.

The first lenses of the first optical layer and the second lenses of the second optical layer are symmetrically arranged with respect to the center 201 of the housing cover 120.

The first optical sweet spot OPL1_C of the first optical layer is shifted from the center 411C of the first display panel 411 in the second direction X2.

The second optical sweet spot OPL2_C of the second optical layer is shifted from the center 412C of the second display panel 412 in the first direction X1 opposite to the third direction X2.

According to an embodiment of FIG. 15, the third direction Y1 is an upward direction of the housing cover 120. The fourth direction Y2 is a downward direction of the housing cover 120. The second direction X2 is directed from the center 201 of the housing cover 120 toward the first display panel 411. The first direction X1 is directed from the center 201 of the housing cover 120 toward the second display panel 412.

According to a head-mounted display device, a glasses-type display device, and display devices that have these forms according to embodiments, the field of view can be expanded and image distortion can be reduced by correcting the location of the optical sweet spot of the lens array.

In addition, according to embodiments, a head-mounted display device, a glasses-type display device and a display device that has these forms have a simple structure and thus reduced fabrication costs.

In concluding the detailed description, those skilled in the art will appreciate that many variations and modifications can be made to the disclosed embodiments without substantially departing from the principles of the present disclosure. Therefore, the disclosed embodiments of the disclosure are used in a generic and descriptive sense only and not for purposes of limitation.

What is claimed is:

1. A mobile display device, comprising:
a first display device that provides images to a user's left eye;
a second display device that provides images to the user's right eye;
a display device housing that accommodates the first display device and the second display device; and
a housing cover that covers a face of the display device housing and includes a first eyepiece aligned with the first display device and a second eyepiece aligned with the second display device,
wherein each of the first display device and the second display device includes a display panel that includes an emission material layer, an optical layer that includes lenses disposed on the emission material layer; and a circuit board disposed at one end of the display panel and that includes a driver circuit that drives the display panel, and
wherein the circuit board of the first display device and the circuit board of the second display device are symmetrically arranged with respect to a center of the housing cover located between the first eyepiece and the second eyepiece.

2. The device of claim 1,
wherein a first circuit board of the first display device is disposed in a first space of the display device housing located in a first direction from the first eyepiece, and
wherein a second circuit board of the second display device is disposed in a second space of the display device housing located in a second direction opposite to the first direction from the second eyepiece.

3. The device of claim 2,
wherein the first display device comprises a first display panel that includes a first emission material layer and a first optical layer, and a first circuit board disposed in the first direction from the first display panel, and
wherein the second display device comprises a second display panel that includes a second emission material layer and a second optical layer, and a second circuit board disposed in the second direction from the second display panel.

4. The device of claim 3, wherein first lenses of the first optical layer and second lenses of the second optical layer are symmetrically arranged with respect to the center of the housing cover.

5. The device of claim 4,
wherein a first optical sweet spot of the first optical layer is shifted from a center of the first display panel in a third direction, and
wherein a second optical sweet spot of the second optical layer is shifted from a center of the second display panel in a fourth direction opposite to the third direction.

6. The device of claim 5, wherein the first lenses include
a first central lens associated with the first optical sweet spot and that is aligned with a center of a sub-pixel of the first emission material layer, and
first peripheral lenses disposed outside the first central lens and that are shifted by a predetermined distance from the center of the sub-pixel of the first emission material layer.

7. The device of claim 6, wherein the predetermined distance of the first peripheral lenses increases away from the first optical sweet spot.

8. The device of claim 7, wherein the first peripheral lenses include
first radius lenses located at a first radius distance from the first optical sweet spot and that are shifted and aligned by a first distance from the center of the sub-pixel, and
second radius lenses located at a second radius distance greater than the first radius distance from the first optical sweet spot and that are shifted and aligned by a second distance from the center of the sub-pixel.

9. The device of claim 5,
wherein the first direction is a direction from the first display panel to the center of the housing cover,
wherein the second direction is a direction from the second display panel to the center of the housing cover,
wherein the third direction is opposite to the first direction, and
wherein the fourth direction is opposite to the second direction.

10. The device of claim 5,
wherein the first direction and the third direction are directions from the center of the housing cover toward the first display panel, and
wherein the second direction and the fourth direction are directions from the center of the housing cover toward the second display panel.

11. The device of claim 5, wherein
the first direction is an upward direction of the housing cover,
the second direction is a downward direction of the housing cover,
the third direction is directed from the center of the housing cover toward the first display panel, and
the fourth direction is directed from the center of the housing cover toward the second display panel.

12. The device of claim 1, wherein the mobile display device is one of a head-mounted display device or a glasses-type display device that provides virtual reality or augmented reality.

13. A head-mounted display device, comprising:
a first display device that provides images to a user's left eye;
a second display device that provides images to the user's right eye;
a display device housing that accommodates the first display device and the second display device; and
a housing cover that covers a face of the display device housing and includes a first eyepiece aligned with the first display device and a second eyepiece aligned with the second display device,
wherein each of the first display device and the second display device includes a display panel that comprises an emission material layer, an optical layer that includes lenses disposed on the emission material layer, and a circuit board disposed at one end of the display panel and that includes a driver circuit that drives the display panel, and
wherein the circuit board of the first display device and the circuit board of the second display device are symmetrically arranged with respect to a center of the housing cover located between the first eyepiece and the second eyepiece.

14. The device of claim 13, wherein
a first circuit board of the first display device is disposed in a first space of the display device housing located in a first direction from the first eyepiece, and
a second circuit board of the second display device is disposed in a second space of the display device housing located in a second direction opposite to the first direction from the second eyepiece.

15. The device of claim 14,
wherein the first display device comprises a first display panel that includes a first emission material layer and a first optical layer, and a first circuit board disposed in the first direction from the first display panel, and
wherein the second display device comprises a second display panel that includes a second emission material layer and a second optical layer, and a second circuit board disposed in the second direction from the second display panel.

16. The device of claim 15, wherein first lenses of the first optical layer and second lenses of the second optical layer are symmetrically arranged with respect to the center of the housing cover.

17. A glasses-type display device, comprising:
a first display device that provides images to a user's left eye;
a second display device that provides images to the user's right eye;
a display device housing that accommodates the first display device and the second display device; and
a housing cover that covers a face of the display device housing and includes a first eyepiece aligned with the first display device and a second eyepiece aligned with the second display device,
wherein each of the first display device and the second display device includes a display panel that includes an emission material layer, an optical layer that includes lenses disposed on the emission material layer; and a circuit board disposed at one end of the display panel and that includes a driver circuit that drives the display panel, and
wherein the circuit board of the first display device and the circuit board of the second display device are symmetrically arranged with respect to a center of the housing cover located between the first eyepiece and the second eyepiece.

18. The device of claim 17, wherein
a first circuit board of the first display device is disposed in a first space of the display device housing located in a first direction from the first eyepiece, and
a second circuit board of the second display device is disposed in the second space of the display device housing located in a second direction opposite to the first direction from the second eyepiece.

19. The device of claim 18,
wherein the first display device comprises a first display panel that includes a first emission material layer and a first optical layer, and a first circuit board disposed in the first direction from the first display panel, and
wherein the second display device comprises a second display panel that includes a second emission material layer and a second optical layer, and a second circuit board disposed in the second direction from the second display panel.

20. The device of claim 19, wherein first lenses of the first optical layer and second lenses of the second optical layer are symmetrically arranged with respect to the center of the housing cover.
